(19) United States
(12) Patent Application Publication
(10) Pub. No.: US 2008/0101006 A1
(43) Pub. Date: May 1, 2008

(54) Hard drive deck

(75) Inventors: Yaw-Tzorng Tsorng, Kuei Shan Hsiang (TW); Hsueh-Chin Lu, Lu Chu Hsiang (TW); Chen-Sheng Tang, Kuei Shan Hsiang (TW)

Correspondence Address: RABIN & Berdo, PC, 1101 14TH STREET, NW, SUITE 500, WASHINGTON, DC, 20005, US

(73) Assignee: Quanta Computer Inc., Tao Yuan Shien (TW)

(21) Appl. No.: 11/783,355

(22) Filed: Apr. 9, 2007

(30) Foreign Application Priority Data
Oct. 30, 2006 (TW) 95219133

(51) Int. Cl. H05K 7/14

(52) U.S. Cl. 361/685

(57) ABSTRACT

A hard drive deck is described. A base portion comprises three support legs and a first fastening portion, wherein each of the three support legs has an opening to be fastened to a computer housing by a screw. A hard drive housing is secured on the base portion. The hard drive hosing comprises an insert opening, a second fastening portion and a third fastening portion, wherein the insert opening allows a hard disk drive to be plugged into. A L-shaped frame comprises a first screw hole, a second screw hole and a positioning pin. The first screw hole and the second screw hole are located on two ends of the L-shaped frame. The first fastening portion and the second fastening portion are secured to the first screw hole and the second screw hole. The positioning pin engages with a positioning hole of the third fastening portion.

### RELATED APPLICATIONS

This application claims priority to Taiwan Application Serial Number 95219133, filed Oct. 30, 2006, which is herein incorporated by reference.

### BACKGROUND

1. Field of Invention

The present invention relates to a hard drive deck for accommodating and connecting a hard disk drive.

2. Description of Related Art

Nowadays, how a space inside a computer system being used is carefully considered and no space should be idle. For instance, a housing of a standard computer server, i.e. a 1-U sever, has been restricted to a specified size. When an unused space exists in its housing, efforts is taken to fill the unused space. Therefore, a non-standard hard drive deck is a choice to fill in the unused space.

### SUMMARY

A hard drive deck includes the following components. A base portion comprises three support legs and a first fastening portion, wherein each of the three support legs has an opening to be fastened to a computer housing by a screw. A hard drive housing is secured on the base portion. The hard drive hosing comprises an insert opening, a second fastening portion and a third fastening portion, wherein the insert opening allows a hard disk drive to be plugged into. A L-shaped frame comprises a first screw hole, a second screw hole and a positioning pin. The first screw hole and the second screw hole are located on two ends of the L-shaped frame. The first fastening portion and the second fastening portion are secured to the first screw hole and the second screw hole. The positioning pin engages with a positioning hole of the third fastening portion.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a top view of a hard drive deck according to one preferred embodiment of this invention; and

FIG. 2 illustrates an exploded view of a hard drive deck according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

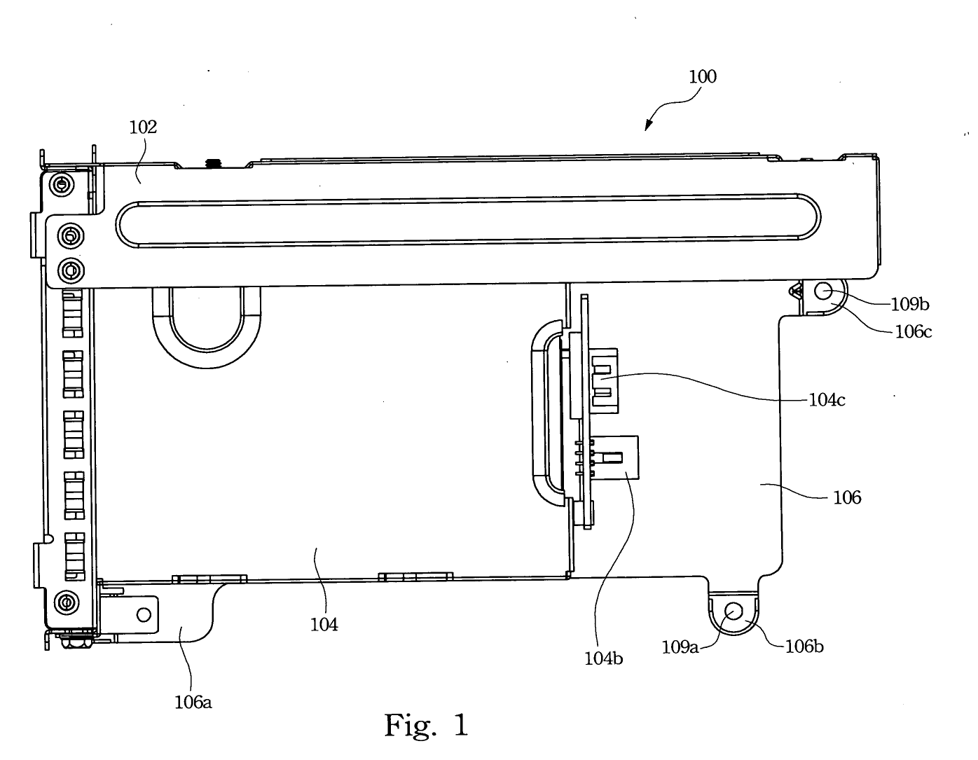

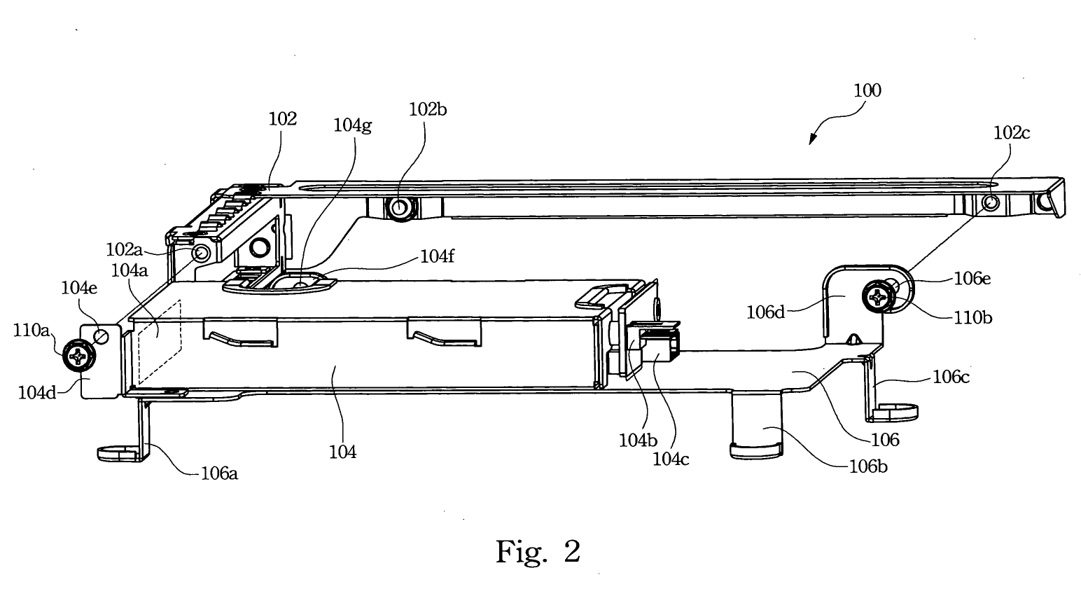

FIG. 1 illustrates a top view of a hard drive deck according to one preferred embodiment of this invention. FIG. 2 illustrates an exploded view of the hard drive deck in FIG. 1.

Please refer to both FIG. 1 and FIG. 2. The hard drive deck 100 is designed to fill in an unused space of a standard computer system. The hard drive deck 100 includes a L-shaped frame 102, a hard drive housing 104 and a base portion 106. The base portion 106 is a metallic rectangular plate with three support legs 106a/106b/106c and a fastening portion 106d. Each support leg has an opening, i.e. openings 109a/109b, the opening of the support led 106a is not illustrated in drawings, where a screw can be screwed through. Three support legs 106a/106b/106c perpendicularly extends from three corners of the rectangular base portion 106.

Metallic hard drive housing 104 is secured on top of the base portion 106. The hard drive housing 104 includes an insert opening 104a, a fastening portion 104d and a fastening portion 104f. The insert opening 104a should be exposed by a computer housing, thereby allowing a hard disk drive to be plugged into. The hard drive housing 104 further includes a power connector 104b and a signal connector 104c, respectively electrically connected with a power supply and a main board of a computer system. When the hard disk drive is inserted into the hard drive housing 104 and coupled to the power connector 104b and the signal connector 104c, the hard disk drive can function properly.

The L-shaped frame 102 surrounds two adjacent edges of the rectangular base portion 106 and two adjacent edges of the hard drive housing 104. The three support legs 106a/106b/106c are not in the area surrounded by the L-shaped frame 102. L-shaped frame 102 includes screw holes 102a/102c and a positioning pin 102b. The screw holes 102a/102c are located on two ends of the L-shaped frame 102. A screw 110a is led through the hole 104e of the fastening portion 104d and screwed into the screw hole 102a (equipped with threads inside). A screw 110b is led through the hole 106e of the fastening portion 106d and screwed into the screw hole 102c (equipped with threads inside). The positioning pin 102b engages with a positioning hole 104g of the fastening portion 104f of the hard drive housing 104. By above-mentioned fastening, the L-shaped frame 102 can be secured to the hard drive housing 104 and the base portion 106. The combination of the L-shaped frame 102, the hard drive housing 104 and the base portion 106 can be readily installed in an unused space of a standard computer system.

According to the embodiment discussed above, the hard drive deck of the present invention can be readily installed in an unused space of a standard computer system by a screw fastening such that all space in the standard computer system is effectively used.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A hard drive deck, comprising:
a base portion, comprising three support legs and a first fastening portion, wherein each of the three support legs has an opening to be fastened to a computer housing by a screw; and
a hard drive housing, secured on the base portion, the hard drive hosing comprising an insert opening, a second fastening portion and a third fastening portion, wherein the insert opening allows a hard disk drive to be plugged into; and
a L-shaped frame, comprising a first screw hole, a second screw hole and a positioning pin, the first screw hole and the second screw hole being located on two ends of the L-shaped frame, wherein the first fastening portion and the second fastening portion are secured to the first screw hole and the second screw hole, the positioning pin engages with a positioning hole of the third fastening portion.

2. The hard drive deck of claim 1, wherein the base portion is a rectangular base portion.

3. The hard drive deck of claim 2, wherein the three support legs extends from three corners of the rectangular base portion.

4. The hard drive deck of claim 3, wherein the three support legs perpendicularly extends from three corners of the rectangular base portion.

5. The hard drive deck of claim 2, wherein the L-shaped frame surrounds two adjacent edges of the rectangular base portion.

6. The hard drive deck of claim 5, wherein the three support legs are not within the area surrounded by the L-shaped frame.

7. The hard drive deck of claim 1, wherein the hard drive housing further comprises a power connector.

8. The hard drive deck of claim 1, wherein the hard drive housing further comprises a signal connector.

9. The hard drive deck of claim 1, wherein the hard drive housing is a metallic hard drive housing.

10. The hard drive deck of claim 1, wherein the base portion is a metallic base portion.
